(19) United States
(12) Patent Application Publication
(10) Pub. No.: US 2025/0112020 A1
(43) Pub. Date: Apr. 3, 2025

(54) BETA TILT SAMPLE HOLDER

(71) Applicant: FEI Company, Hillsboro, OR (US)

(72) Inventors: Albert Visscher, Veldhoven (NL); Johannes Antonius Maria van den Oetelaar, Eindhoven (NL); Edwin Verschueren, Mierlo (NL); Ross Savage, Eindhoven (NL); Emma Julia Elisabeth Hoes, Son en Breugel (NL)

(21) Appl. No.: 18/888,100

(22) Filed: Sep. 17, 2024

Related U.S. Application Data
(60) Provisional application No. 63/586,736, filed on Sep. 29, 2023.

(51) Int. Cl. H01J 37/20

(52) U.S. Cl. CPC H01J 37/20; H01J 2237/2006; H01J 2237/2007

(57) ABSTRACT

Aspects of a sample holder configured for an analytical instrument system, as well as components and methods for reproducible sample motion are described. An apparatus for coupling a specimen with an instrument can include a rear lever arm, a front lever arm, coupled with the rear lever arm, and a sample cradle, coupled with the front lever arm via an S-flexure.

### CROSS-REFERENCE TO RELATED APPLICATIONS

This applications claims the benefit of the prior-filed provisional application, serial number U.S. 63/586,736, entitled, “HIGH ACCURACY BETA-TILT HOLDER,” filed on Sep. 29, 2023, the contents of which are incorporated herein by reference, in their entirety.

### TECHNICAL FIELD

Embodiments of the present disclosure are directed to charged particle microscope systems and components, as well as algorithms and methods for their operation. In particular, some embodiments are directed toward reproducible sample motion.

### BACKGROUND

Current double tilt holders, enabling an alpha x-tilt and a beta y-tilt of a sample, are considered acceptable when they exhibit hysteresis up to 1.5 μm. For the customer this means unpredictable behavior during navigation including trial and error to achieve the desired-angle (e.g., zone-axis alignment). A move of +x° followed by a return move of −x° can yield an undesirable change in sample position (e.g., about 1.5 μm). Hysteresis in the sample position at that length scale can result in significant image drift, implicating additional drift correction procedures and limiting the extent to which sample navigation can be automated. There is a need, therefore, for improved TEM sample holders designed to minimize hysteresis.

### BRIEF SUMMARY

Aspects of a sample holder configured for an analytical instrument system, as well as components and methods for reproducible sample motion are described. In a first aspect, an apparatus for coupling a specimen with an instrument is described in reference to FIGS. 1-6. The apparatus can include a rear lever arm, a front lever arm, coupled with the rear lever arm, and a sample cradle, coupled with the front lever arm via an S-flexure.

In some embodiments, the S-flexure defines a deformed state and a relaxed state. The S-flexure can be reversibly transitioned between the deformed state and the relaxed state. A transition between the deformed state and the relaxed state can induce a pivot of the sample cradle. The pivot can describe an angle from about-10 degrees to about 10 degrees, relative to a lateral axis of the sample cradle.

In some embodiments, the apparatus further includes a holder body. The sample cradle can be mechanically coupled with the holder body via a V-flexure. The rear lever arm can be mechanically coupled with the front lever arm via a pivot coupling. A vertical translation of a first end of the rear lever arm can induce a complementary translation of the front lever arm in the vertical direction.

The front lever arm can be mechanically coupled with the rear lever arm via a diaphragm. The apparatus can further include a holder body. The diaphragm can be mechanically coupled with the holder body. The diaphragm can define a vacuum-tight seal with the holder body. The front lever arm can be mechanically coupled with a damper mass via a viscoelastic ligature. The damper mass can be physically separate from the front lever arm. The damper mass can be disposed in an aperture formed through the front lever arm. The aperture can be formed at a position on the front lever arm corresponding to a resonant mode or otherwise elevated amplitude of vibratory motion in the front lever arm.

In some embodiments, the rear lever arm is mechanically coupled with a linear drive. The linear drive can be configured to translate a first end of the rear lever arm in a vertical direction. The rear lever arm can be mechanically coupled with a strain gauge. The apparatus can further include an optical encoder configured to measure a spatial displacement of the linear drive. The apparatus can further include a force compensation mechanism, mechanically coupled with the linear drive actuator and configured to oppose a force resulting from a translation of the first end by the actuator.

In a second aspect, a charged particle beam system is described in reference to FIGS. 1-6. The system can include a source of charged particles, configured to generate a beam of charged particles, and an objective section configured to direct at least a portion of the beam of charged particles through a sample holder apparatus of the first aspect, in one or more embodiments. In some embodiments, the system can be configured to direct at least the portion of the beam of charged particles through the sample cradle of the sample holder.

The terms and expressions which have been employed are used as terms of description and not of limitation, and there is no intention in the use of such terms and expressions of excluding any equivalents of the features shown and described or portions thereof, but it is recognized that various modifications are possible within the scope of the claimed subject matter. Thus, it should be understood that although the present claimed subject matter has been specifically disclosed by embodiments and optional features, modification and variation of the concepts herein disclosed can be resorted to by those skilled in the art, and that such modifications and variations are considered to be within the scope of this disclosure as defined by the appended claims.

### BRIEF DESCRIPTION OF THE SEVERAL VIEWS OF THE DRAWINGS

The foregoing aspects and many of the attendant advantages of the present disclosure will become more readily appreciated as the same become better understood by reference to the following detailed description, when taken in conjunction with the accompanying drawings.

FIG. 1 is a schematic diagram illustrating an example charged particle beam system, in accordance with some embodiments of the present disclosure.

FIG. 2 is a schematic diagram illustrating an example sample holder apparatus, in accordance with some embodiments of the present disclosure.

FIGS. 3A-3C are schematic diagrams illustrating internal components of the sample holder apparatus of FIG. 2, in accordance with some embodiments of the present disclosure.

FIGS. 4A-C are schematic diagrams illustrating an example sample cradle of the holder apparatus of FIGS. 2-3C in different conformations, in accordance with some embodiments of the present disclosure.

FIG. 5 is a schematic diagram illustrating an example force compensation mechanism, in accordance with some embodiments of the present disclosure.

FIGS. 6A-6B are schematic diagrams illustrating an example measurement system, in accordance with some embodiments of the present disclosure.

In the drawings, like reference numerals refer to like parts throughout the various views unless otherwise specified. Not all instances of an element are necessarily labeled to reduce clutter in the drawings where appropriate. The drawings are not necessarily to scale, emphasis instead being placed upon illustrating the principles being described.

### DETAILED DESCRIPTION

While illustrative embodiments have been illustrated and described, it will be appreciated that various changes can be made therein without departing from the spirit and scope of the disclosure. In the forthcoming paragraphs, embodiments of a sample holder configured for an analytical instrument system, components, and methods for reproducible sample motion are described. Embodiments of the present disclosure focus on charged particle beam techniques and related instruments in the interest of simplicity of description. To that end, embodiments of the present disclosure are not limited to such instruments, but rather are contemplated for sample motion components and systems where imaging and/or microanalysis of a sample can be complicated by hysteresis after multiple sample motions, such as a pivot of a sample relative to a beam of energetic particles, such as photons, ions, electrons, or the like. Similarly, while embodiments of the present disclosure focus on sample holder components of transmission electron microscopes, additional and/or alternative analytical instrument systems are contemplated, including but not limited to scanning electron microscopes, scanning transmission electron microscopes, focused ion beam systems, laser systems, optical microscopy systems, synchrotron beam systems, x-ray systems, or the like.

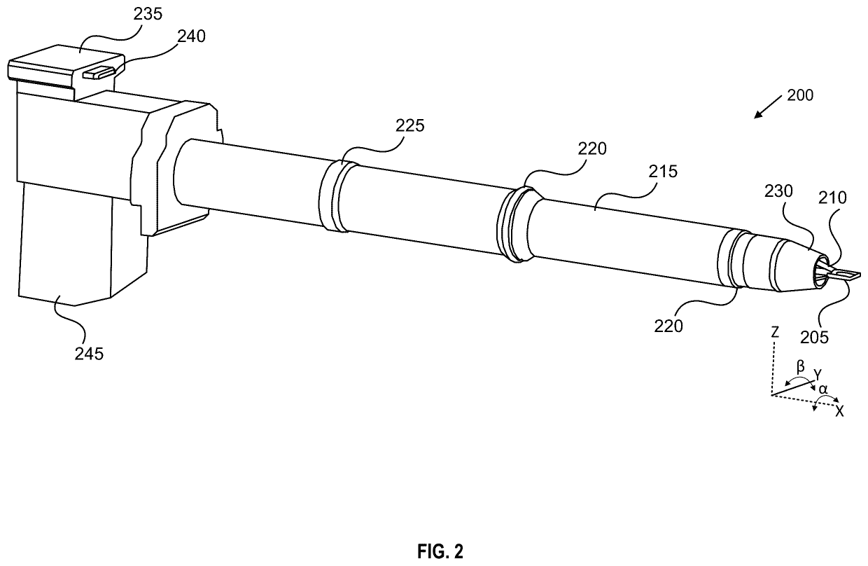

Embodiments of the present disclosure include a high accuracy beta-tilt TEM sample holder designed to reduce hysteresis by way of flexure-based kinematic guidance. In the forthcoming disclosure, the term “beta-tilt” refers to a pitching or y-tilt motion of a sample cradle, and the term “alpha-tilt” refers to a rolling or x-tilt motion of the sample cradle, as as illustrated in FIG. 2. In some embodiments, the holders of the present disclosure also perform an “alpha-tilt” that entails a rotation of the holder about a lateral axis of the holder, identified as a lateral x-axis in the FIGS. 2-6. The alpha-tilt can induce an x-tilt motion of the sample cradle, among other types of motion in one or more degrees of freedom. Based at least in part on removing friction-based joints, holders of the present disclosure address hysteresis by reducing sources of irreproducible variation in motion. Holders of the present disclosure benefit from improved throughput and predictability for connectivity and sample loading. Further, mechanical kinematic constraints disposed between a measurement system and a load (e.g., a sample disposed in a sample cradle) can be flexure-based. Similarly, friction-based interactions (e.g., a nut and spindle drive) can be isolated before a point where motion is measured as an approach to reducing the friction instability effect on precise motion of the load.

In an example embodiment of a holder, flexure-based kinematic guidance includes defining two pivots and a vacuum interface. The axis of a first pivot can be formed by a virtual intersection of two sides of a “V”-flexure, where the virtual intersection defines a line that can coincide with a mid-line of a sample cradle along a lateral y-axis. The holder can define a relaxed state and one or more deformed states, corresponding to different tilt angles of the sample cradle. An “S”-flexure allows a change in angle and distance to the front lever arm in accordance with a tilt of the holder.

A second pivot can include a metal diaphragm that can function as a pivot and as a vacuum/ambient interface. Advantageously, motion induced by time-variant pressure differential across the diaphragm (e.g., environmental pressure variations due to door swings, etc.) that would otherwise affect the precision of sample positioning can be attenuated by the S-flexure. In this way, the S-flexure can reduce the effect of this axial movement of the diaphragm on the angle of the sample since the “S”-flexure is relatively compliant in the lateral x-direction. A buckling leaf-spring can be added as a high-strain measurement location for the strain gauge measurement system. Between the measurement point and the load (-tilt) motion can be elastically guided, offering the benefit of significantly reduced friction. A tuned-mass damper can be built into the front lever arm to at least partially attenuate undamped resonant motion in the driving direction (e.g., vertical z-direction). The z-direction dynamic mode of the front lever arm can lead to disturbances in the beta-tilt angle of the sample, which can have a component in the x-direction. At a nonzero alpha-tilt angle, the resonant mode also has a component in the lateral y-direction. Lateral y-direction displacement introduces image blur artefacts that are highly visible and reduce spatial resolution significantly. To that end, attenuating motion in the y-direction represents a significant improvement over the current art.

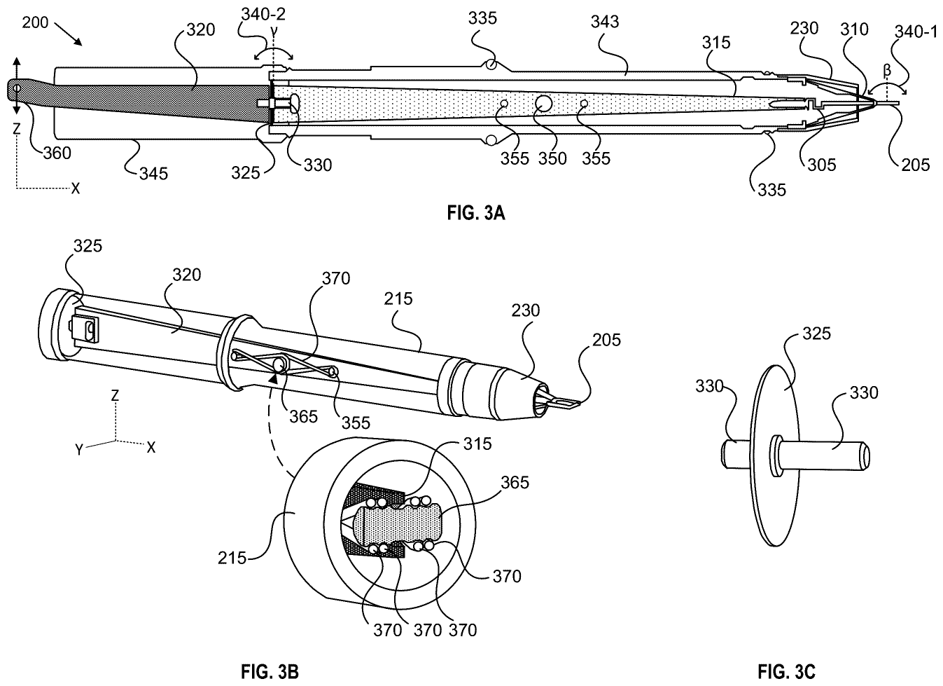

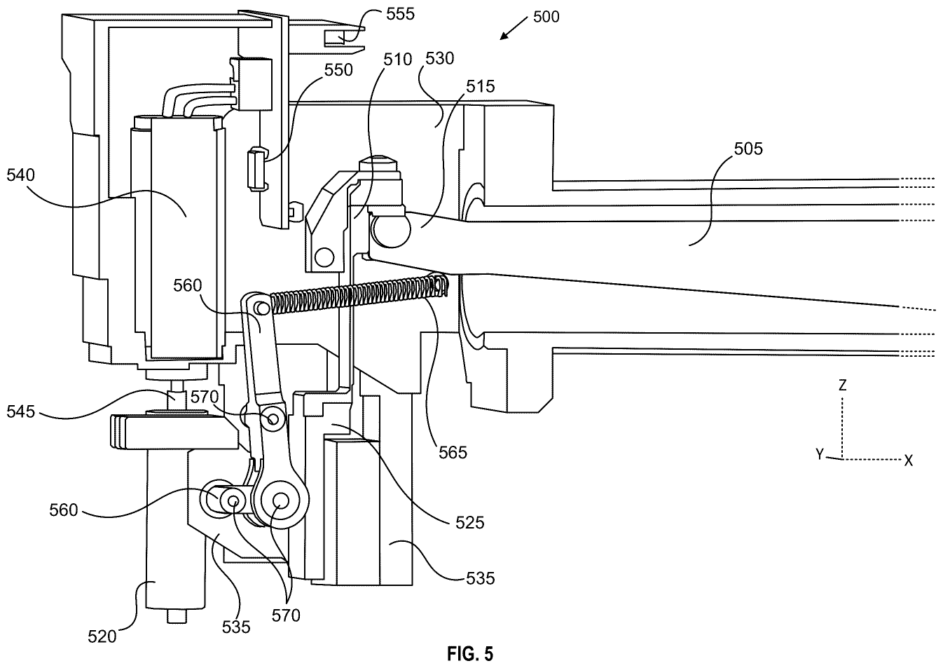

Embodiments of the present disclosure include systems, components, methods, algorithms, and non-transitory media storing computer-readable instructions for reproducible sample motion. Holders of the present disclosure present numerous advantages over tilt holders of the current art. For example, embodiments of the present disclosure include structures configured for negligible or no friction contact, as described in more detail in reference to FIGS. 5-7. Such components improve motion stability and reduce hysteresis significantly. In another example, sample holders of the present disclosure situate actuation and measurement systems in ambient conditions, outside a vacuum environment of a charged particle beam system, as described in more detail in reference to FIGS. 3A-3C. This approach offers the advantage of reduced cost, complexity, and technical risk attributable to exposing internal components to vacuum (e.g., electrical breakdown within the holder). To that end, embodiments of the present disclosure combine a pivot mechanism with a vacuum feedthrough element, as described in more detail in reference to FIGS. 3A-3C, which offers the added benefit of reduced weight and improved integration of the pivot mechanism with measurement and actuation elements situated on the ambient side of the vacuum feedthrough.

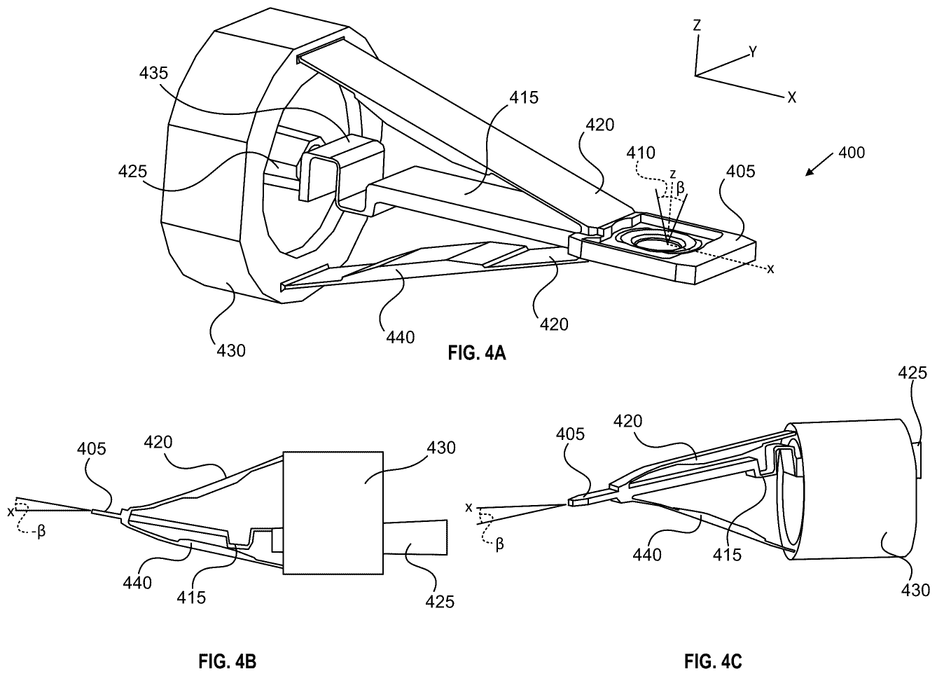

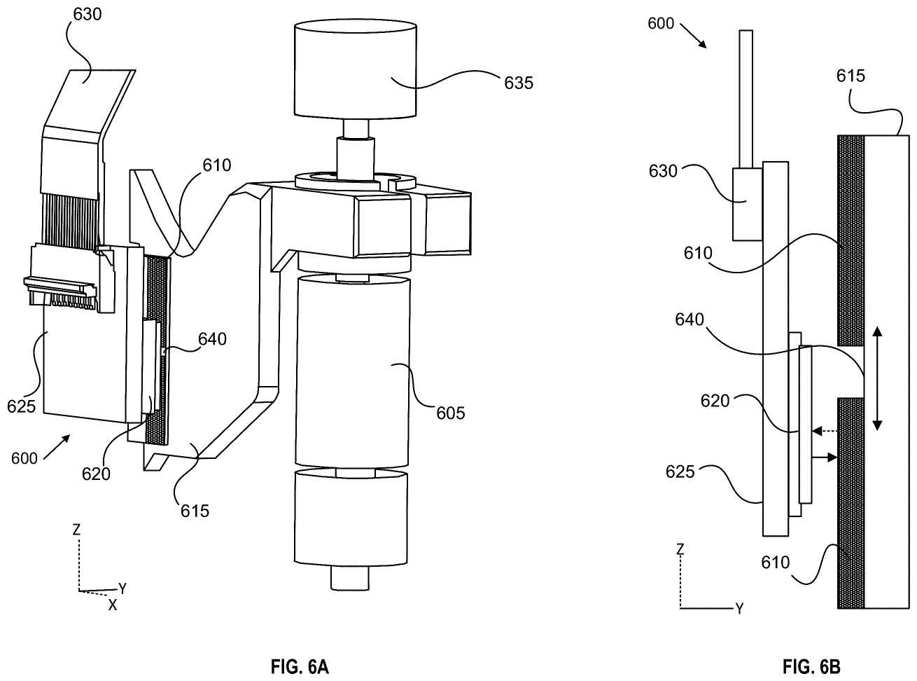

In another example, embodiments of the present disclosure include a registered measurement system, as described in more detail in reference to FIGS. 6A-6B. In contrast to a referential measurement system, the registered measurement systems of the present disclosure can approach an absolute measurement system in terms of functionality. In this context, an “absolute” measurement system provides a precise measurement of a motion of at least one component of the pivot mechanism, which can be used to determine a pivot angle of a sample cradle (as described in reference to FIGS. 4A-4C) with improved precision and accuracy, while also reducing the weight of the measurement component and significantly reducing power dissipation, with attendant improvement in thermal drift. Finally, embodiments of the present disclosure include a tuned-mass damper, as described in more detail in reference to FIGS. 3A-3C. The tuned-mass dampers of the present disclosure can attenuate a driving-direction vibratory mode conducted through the components of the pivot mechanism and/or through the feedthrough, while keeping an overall mass of the pivot mechanism relatively low, as compared to pivot holders of the current art. Overall, embodiments of the present disclosure offer the advantage of improved dynamic performance of a transmission electron microscope (TEM) stage, at least in part by reducing hysteresis in pivot motion, improving cost and complexity of the holder elements of the stage, and improving stability and reproducibility of motion indicated by a user of the TEM.

The following detailed description focuses on embodiments of a sample holder for a TEM system, but it is contemplated that additional and/or alternative instrument systems can be improved through the use of the techniques described. In an illustrative example, instrument systems can include analytical instruments configured to generate reproducible sample motion in evacuated systems configured to interrogate a material sample (e.g., synchrotron beam systems, electron beam systems, ion beam systems, x-ray diffraction systems, or the like).

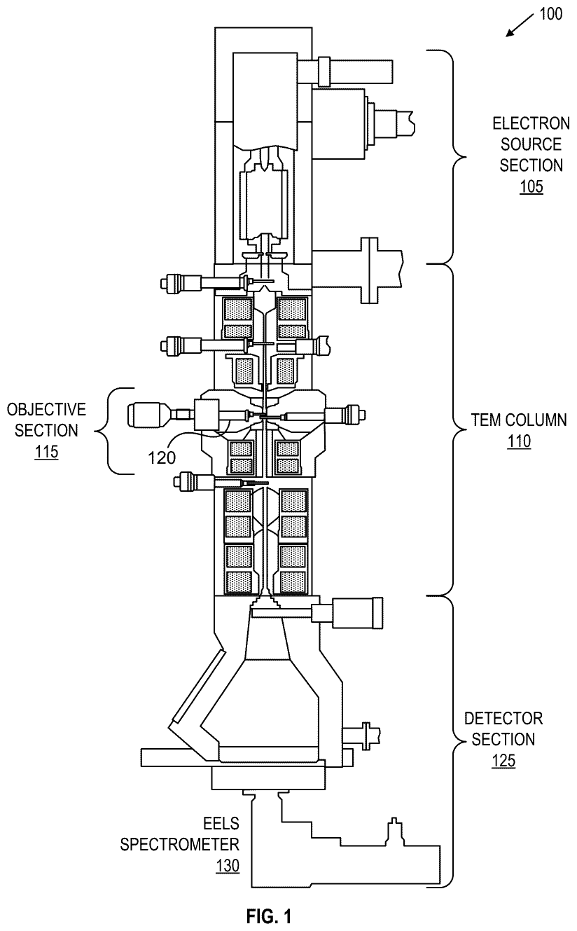

FIG. 1 is a schematic diagram illustrating an example charged particle beam system 100, in accordance with some embodiments of the present disclosure. In the following description, details of internal components and functions of the example beam system 100 are described in the context of a transmission electron microscope (TEM) with some elements omitted for simplicity and to focus description on embodiments of the present disclosure, as described in more detail in reference to FIGS. 2-7, and on techniques for reproducible sample motion. The example TEM system 100 includes an electron source section 105, a TEM column 110 including an objective section 115, and a detector section 125. The present disclosure focuses on techniques for improving the performance of a sample holder 120, with embodiments of the present disclosure including the sample holder 120 being configured to reduce hysteresis in a pivoting motion of a sample cradle.

In brief, the electron source section 105 includes electronics configured to energize a source of charged particles, which can include a high-voltage field-emission source and/or other sources of emitted electrons, such that a beam of electrons is formed and conducted through a vacuum into the TEM column 110. The TEM column 110 includes components for beam forming, including electromagnetic lenses and/or electrostatic lenses, and multiple apertures to control properties of the beam of electrons. TEM column components include condenser lenses, objective lenses, projector lenses, aberration correctors, deflectors, stigmators, among others, as well as corresponding apertures. The sample holder 120 is configured to host a sample through which the beam of electrons can be transmitted. In the case of EELS microanalysis, the beam can be focused onto the sample for spot mode analysis (e.g., through the action of one or more objective lenses) or the beam can be passed through the sample in parallel illumination mode (or at least partially defocused) to gather data from a relatively large sample area.

In some embodiments, the objective section 115 includes a magnetic immersion objective lens assembly, configured to immerse a sample in an objective field. Advantageously, disposing the sample in the objective field can provide a resolution for STEM mode operation of about 0.05 nm. In this context, immersion in the objective field refers to disposing the sample in the magnetic field of the objective lens that extends into the space between the sample and a pole piece of the objective lens. Such immersion significantly reduces possible aberrations of the objective lens, which otherwise would reduce the spatial resolution of the microscope. At a spatial resolution of about 0.05 nm, and corresponding levels of magnification, hysteresis in motion on the scale of ±1.5 μm can introduce significant drift in the field of view (FOV) and/or losing a feature of interest in the FOV.

In some embodiments, charged particle microscope system 100 operates in a field-free (e.g., non-immersion) STEM mode, where the objective lens is not used to focus charged particles onto the sample. In some systems, a mini-condenser lens upstream of the specimen can act as probe-forming lens and a Lorentz lens downstream of the specimen can act as a first imaging lens to provide at least some of the functions of the objective lens. In field-free STEM mode, detector data can be generated at a spatial resolution of about 0.5 nm. As for immersion mode, for a spatial resolution of about 0.5 nm, and corresponding levels of magnification, hysteresis in motion on the scale of ±1.5 μm can introduce significant drift in the field of view (FOV) and/or losing a feature of interest in the FOV.

The detector section 125 includes one or more type of detector, sensor, screen, and/or optics configured to generate images, spectra, and other data for use in sample imaging and/or microanalysis. For example, the imaging section can include a scintillator screen, binoculars, transmission electron microscopy (TEM) detector(s) (e.g., pixelated electron detector, secondary electron detector, segmented STEM detectors, pixelated camera(s), and/or electron energy loss spectroscopy (EELS) spectrometer(s) 130, among others). A pivot/tilting motion can benefit some microanalysis techniques, such as electron crystallography, which can be used for 3D reconstruction of crystalline materials (e.g., crystalline proteins, for which meaningful structural information is found at a spatial resolution from about 1 nm to about 3 nm) based at least in part on on generating images at different pivot angles.

FIG. 2 is a schematic diagram illustrating an example sample holder apparatus 200, in accordance with some embodiments of the present disclosure. The example holder 200 of FIG. 2 is an embodiment of the sample holder 120 of FIG. 1, in that it is configured for integration with a TEM system. To that end, the example sample holder apparatus 200 includes a sample cradle 205, a pivot mechanism 210, a holder body 215, one or more vacuum couplers 220, a vacuum feedthrough 225, a thermal shield 230, control circuitry 235, an electrical coupler 240, and a motion assembly 245. In reference to the sample cradle 205 and the holder body 215, the example holder 200 defines a lateral “x” axis and a vertical “z” axis, with a third axis “y” defined normal to both the lateral and vertical axes.

The example holder 200 is configured to reproducibly pivot the sample cradle 205, based at least in part on a transfer of motion from the motion assembly 245 to the pivot mechanism 210. The pivot mechanism is described in more detail in reference to FIGS. 3A-4C. The motion assembly 245 can include additional and/or alternative components, such as a force compensator mechanism and a measurement system, as described in more detail in reference to FIGS. 5-6B.

The holder body 215 is configured to couple with one or more corresponding features of the TEM system (e.g., a receiver of the objective section 115 of FIG. 1) with which it is associated. To that end, the vacuum coupler(s) 220 can include one or more elements that, together with the TEM system, define a vacuum tight seal against a low pressure environment within the TEM system. In this way, the holder 200 can be introduced into the TEM system and maintain a vacuum environment of the TEM system (e.g., the TEM column 110), and further enable an internal volume of the example holder 200 to be evacuated, as described in more detail in reference to FIGS. 3A-3C.

The vacuum feedthrough 225 can include one or more internal components (e.g., the diaphragm 325 of FIGS. 3A-3C) that together define a vacuum tight seal within the holder body 215. The example holder 200 is thereby configured to maintain a portion of its internal volume and some internal components at an ambient pressure (e.g., at external room pressure), rather than at the reduced pressure of the vacuum environment internal to the TEM system. In some embodiments, the control circuitry 235, the motion assembly 245, and at least a portion of the pivot mechanism 210 can be maintained at ambient pressure.

The thermal shield 230 can be or include a tapering cylindrical portion that at least partially surrounds a portion of the pivot mechanism 210. The thermal shield 230 can be or include a material that is at least partially reflective of thermal radiation, such that heat that is conducted toward the sample cradle 205 through the pivot mechanism 210 contributes negligible or no background noise to thermally sensitive detectors that would otherwise be affected by the heat radiating from the sample holder 200. In an illustrative example, the thermal shield 230 can be or include a thermally absorptive material (e.g., a ceramic or refractory material) that is at least partially coated with a thermally reflective material (e.g., gold). In an example, an inner surface, facing the pivot mechanism 210, can be faced in a gold coating that exhibits a significant reflectivity to photons in the infrared range. Further, the thermal shield 230 can also/alternatively reflect and/or attenuate at least a portion of the heat load that would otherwise be conducted toward the pivot mechanism 210 (e.g., via the holder body 215 or from a radiative heat source in the environment of the pivot mechanism 210). Advantageously, attenuating the heat flux into the flexures of the pivot mechanism 210 can reduce the period of thermal instability that contributes to image drift.

The control circuitry 235 can include components configured to receive one or more types of input signals and electrical power, to generate control signals to actuate the motion assembly 245, to generate measurement data describing a motion of the pivot mechanism 210, and/or to generate one or more output signals. At least a portion of these signals and data can be communicated with an external system via the electrical coupler 240, which can be or include a connector that conforms with one or more input/output interface standards. In some embodiments, the electrical coupler 240 can include a near-field transceiver, such that input signals and/or output signals can be communicated via a wireless link with a computer system.

FIG. 3A-3C is a schematic diagram illustrating internal components of the example sample holder apparatus 200 of FIG. 2, in accordance with some embodiments of the present disclosure. The internal components include those of the pivot mechanism 210, the holder body 215, vacuum coupler(s) 220, and the vacuum feedthrough 225, among others. FIGS. 3A-3C further illustrate internal components and structures of the example holder 200 that confer various advantages over holders of the current art, with respect to reproducible sample motion (e.g., attenuated hysteresis), among other advantages. For example, FIG. 3A illustrates structures configured to transfer vertical motion into a first pivoting motion at the sample cradle 205. FIG. 3B illustrates internal structures configured to attenuate vibrations. FIG. 3C illustrates internal structures configured to transfer vertical motion into a second pivoting motion and to define a vacuum tight seal with at least part of the holder body 215.

FIG. 3A illustrates an “S-flexure” 305, a v-flexure 310, a front lever arm 315, a rear lever arm 320, a diaphragm 325, a force transfer element 330, and one or more seals 335. Relative to the lateral “x” axis of the sample cradle 205 and the holder body 215, one or more pivots 340 can be defined by the mechanical couplings between the various components of the pivot mechanism 210. The holder body 215 can include one or more segments, such that the front lever arm 315 corresponds to a forward segment 343 of the holder body 215 and the rear lever arm 320 corresponds to a rearward segment 345 of the holder body 215. As described in more detail in reference to FIG. 3B, the front lever arm 315 can include one or more apertures 350 and one or more pegs 355.

A first pivot 340-1 can be defined for the sample cradle 205, such that a lateral face of the sample cradle 205 can be oriented at a first angle, β, which can be defined relative to the lateral, x, axis and/or relative to the vertical, z, axis. A second pivot 340-2 can be defined for the assembly of lever arms 315 and 320, such that substantially opposing pivoting motions of the front lever arm 315 and the rear lever arm 320 can together define a second angle, Y, of the second pivot 340-2. In some cases, the first angle, β, can be from about 0 degrees to about ±40 degrees, including subranges, fractions, and interpolations thereof, in a positive z-direction or a negative z-direction. For example, β can be about ±30 degrees, about ±20 degrees, about ±10 degrees, about ±5 degrees, about ±1 degrees, or the like.

The mechanical coupling of the rear lever arm 320 with the front lever arm 315 via the force transfer element 330, and that of the sample cradle 205 with the front lever arm 315 via the flexures 305 and 310 can cause a substantially vertical motion of a first end 360 of the rear lever arm 320 to induce a first pivoting motion of the sample cradle 205 in accordance with the first pivot 340-1 and a second pivoting motion of the first lever arm 315 in accordance with the second pivot 340-2. As described in more detail in reference to FIGS. 4A-4C, the sample cradle 205 can be coupled with the front lever arm 320 via the S-flexure 305. The sample cradle 205 can be coupled with the holder body 215 via the v-flexure 310. The combination of s-flexure coupling and v-flexure coupling can constrain the motion of the sample cradle 205 to that of the first pivot 340-1. Advantageously, the constrained motion of the sample cradle 205 can be substantially free of hysteresis over a pitch of about 1.5 μm, examples of which are shown in FIGS. 4B-4C.

FIG. 3B illustrates internal structures directed at improving the physical stability of the sample cradle 205, as well as addressing sources of noise in charged particle microscope signals that originate from the sample holder mechanism. As described in more detail in reference to FIG. 2 and FIG. 3A, the thermal shield 230 is disposed at least partially around the flexures 305 and 310, as an approach to attenuating thermal radiation that can emanate from the area of the sample cradle 205. The example holder 200 includes an inertial mass damper 365, disposed at least partially in an aperture 350 of the front lever arm 315. The aperture 350 can be formed at a position on the front lever arm 315 that corresponds to a resonant mode or otherwise elevated amplitude of vibratory motion in the front lever arm. For example, where a mechanical vibration of the instrument exhibits a characteristic frequency composition (e.g., as measured and determined using Fourier transform), a position of a resonant mode in the front lever arm 315 can be determined (e.g., using numerical methods, analytical techniques, etc.). To that end, the mass of the inertial mass damper 365 can be tuned to the resonant mode as an approach to damp the resonant motion of the holder components.

The damper 365 can be suspended in the aperture 350, offset from the front lever arm 315, by one or more ligatures 370. For example, the damper 365 can define one or more surface features configured to receive the ligature(s) 370, such that motion in the lateral y-direction of the damper 365 is substantially constrained. In this way, the damper 365 can attenuate periodic and/or otherwise transient motion of the front lever arm 315 (e.g., random motion) that could propagate to the sample cradle 205, via the s-flexure 305. In some embodiments, the ligature(s) 370 include(s) a viscoelastic material that is vacuum-stable, such as n-butadiene or other vacuum-stable rubber. In some embodiments, a inertial mass damper 365 can be configured as a tuned-mass absorber that is tuned to offset motion of the holder components by out-of-phase motion of the damper mass, thereby attenuating the amplitude of the motion of the holder components. The damper 365 can be coupled with the front lever arm 315 using from one to eight ligatures, including interpolations thereof. For example, the example holder 200 is shown with a symmetric arrangement of two ligatures 370 on either side of the front lever arm 315.

FIG. 3C illustrates the diaphragm 325 and force transfer element 300 in more detail. The diaphragm 325 can be or include a material that can form a vacuum-tight seal between two segments of the holder body 215 (e.g., the forward segment 343 and the rearward segment 345 of the holder body 215). The diaphragm 325 can include a metal, an elastomer, a polymer, or combinations thereof. The force transfer element 300 can be a rigid element or an at least partially flexible element, which can be coupled with the diaphragm 325, such that a substantially vertical z-oriented force applied to one end of the force transfer element 300 can be at least partially converted to a pitching motion of of the force transfer element 300 based at least in part on a constraining effect imposed by the diaphragm 325. Advantageously, the diaphragm 325 can aid the conversion of a substantially linear-vertical motion of the first end 360 of the rear lever arm 320 to a pivoting motion at the sample cradle 205.

FIGS. 4A-C are schematic diagrams illustrating an example sample holder apparatus 400 of in a relaxed state and different deformed states, in accordance with some embodiments of the present disclosure. The example holder 400 is an example of the sample holder sample holder 120 of FIG. 1 and the sample holder 200 of FIGS. 2-3C. FIG. 4A illustrates the example holder 400 in the relaxed state. FIGS. 4B-4C illustrate the example holder 400 in a deformed state, in various conformations. FIGS. 4A-4C together illustrate a reversible pitching motion of a sample cradle 405, which is an example of the sample cradle 205 of FIGS. 2-3C. The pitching motion is substantially constrained in the lateral-y direction, based at least in part on on kinematic guidance provided by flexures, resulting in a first pivot 410 in a plane defined by the lateral x-axis and the vertical z-axis, as identified in FIG. 4A.

The pivot 410 is substantially constrained in the lateral-y direction by an S-flexure 415 and a V-flexure 420, coupled with the sample cradle 405. The S-flexure 415 includes an S-shaped spring 435 coupled with a front lever arm 425, which is an example of the front lever arm 315 of FIGS. 3A-3B. The combined effect of the S-flexure 415 and the V-flexure 420 is to convert at least a portion of a pitching motion of the front lever arm 425 into an opposing pitching motion of the sample cradle 405. The V-flexure 420 can include one or more spring elements 440 that can substantially constrain a flexing of the V-flexure 420 to a region between the sample cradle 405 and the spring elements 440, as illustrated in FIGS. 4B-4C.

FIG. 4A illustrates the relaxed state of the sample holder 400 that corresponds to the front lever arm 425 being substantially aligned with the sample cradle 405 with respect to the lateral axis, x. The various states can also be described in terms of the strain applied to the S-flexure 415 and/or the V-flexure 420, where the relaxed state corresponds to negligible or no strain in the flexures 415-420, while the deformed state(s), two examples of which are illustrated in FIGS. 4B-4C, correspond to non-negligible or nonzero strain in the flexures 415-420. Further, the deformed state(s) exhibit a nonzero angle, β, relative to the lateral axis, x, while the relaxed state exhibits a negligible or substantially zero value for the angle β. As shown in FIGS. 4B-4C, the angle, β, can be given a sign defined in reference to a rotation about the lateral y-axis, such that a clockwise motion about the lateral y-axis is positive. The sign is defined differently in some embodiments.

The pivoting motion of the sample cradle 405 is facilitated by the opposing motion of the front lever arm 425, a portion of the range being illustrated in FIG. 4B and FIG. 4C. As described in more detail in reference to FIG. 3A, the motion of the front lever arm 425 is facilitated, in turn, by opposing pivoting motion of a lever arm (e.g., rear lever arm 320 of FIG. 3A) that is coupled with a linear translator. In this way, the pitch angle of the sample cradle 405 can be modified with a relatively high level of precision and with significantly improved reproducibility by vertically translating the rear lever arm, which causes the front lever arm 425 to pivot about the fulcrum at the diaphragm (e.g., the diaphragm 325 of FIGS. 3A-3C). The range of motion of the front lever arm 425 can be constrained at least in part by the V-flexure 420 and the conformation of the S-flexure 415 for example, the S-shaped spring 435 can contact a spring element 440 at one extent of the range of motion of the front lever arm 425.

The sample cradle 405 can include structures configured to host a sample carrier. The structures can include a recessed receptacle shaped to receive a TEM sample grid (e.g., a carbon-covered copper grid, etc.) and/or a material sample prepared from a larger bulk sample. In an illustrative example, the sample cradle can be configured to retain a section of a cryogenically frozen material (e.g., a crystalized protein) that is substantially transparent to electrons and/or a section of a CMOS material (e.g., a multi-layer integrated circuit wafer sample). To that end, the sample cradle can include retaining elements, such as a groove, clamp, spring, or the like, enabling the sample cradle 405 to pivot with negligible or no relative motion of a sample disposed therein.

FIG. 5 is a schematic diagram illustrating an example force compensation mechanism and linear drive system 500, in accordance with some embodiments of the present disclosure. FIG. 5 illustrates a sectioned view through an example sample holder (e.g., holder 120 of FIG. 1, example holder 200 of FIG. 2) on a plane defined by the lateral x-axis and the vertical z-axis. The view omits some internal components of the example holder to focus description on the example system 500. The example system 500 is configured to generate a reproducible motion of a rear lever arm 505 (an example of the rear lever arm 320 of FIG. 3A) that is characterized by significantly reduced hysteresis in vertical motion, as compared to sample holders of the current art. To that end, the rear lever arm 505 is coupled with a force transfer element 510 at a first end 515 of the rear lever arm 505. The force transfer element 510 can be configured for substantially linear translation in the vertical z-direction with negligible or no friction (e.g., using slides, bearings, etc.). For example, the force transfer element 510 can be coupled with a linear drive 520 via a sliding member 525.

The linear drive 520 can be or include components configured to generate a linear motion in the vertical z-direction, based at least in part on at least partially constraining the motion of the sliding member 525 through mechanically coupling the sliding member with a holder body 530 and/or the linear drive 520 via one or more coupling elements 535. In this way, the motion of the linear drive 520 can be substantially aligned with the vertical z-axis of the sample cradle (not shown). In some embodiments, the linear drive 520 is configured to convert a rotational motion into a linear motion. For example, a motor 540 can be coupled with a drive shaft 545 that can be threaded and/or can be coupled with one or more threaded elements, configured to mesh with a corresponding threaded surface of the linear drive 520. Rotation of the shaft 545 can induce a substantially unilateral translation of the linear drive 520 in the vertical z-direction.

As part of reducing hysteresis and improving precision of tilt/pitch of the sample cradle (e.g., sample cradle 205 of FIG. 2), example system 500 includes control circuitry 550 configured to receive one or more signals from a control system (e.g., control systems of a charged particle beam system) via one or more electrical couplers 555. In some embodiments, the control circuitry 550 is configured to receive a drive signal from a control system that is generated in response to a user instruction to tilt a sample by a given angle. The drive signal can include a voltage signal actuating the motor 540 that can be gated by a measurement signal, such that the motor 450 is driven in a given direction (e.g., corresponding to the sign of the voltage signal) concurrent with a measurement of a position of the linear drive 520 and/or one or more coupling elements 535. Example embodiments of the measurement technique are described in more detail in reference to FIGS. 6A-6B.

A force compensation mechanism of the example system 500 includes components configured to counteract the force resulting from the strain applied to the flexures coupling the sample cradle with the lever arms. As described in more detail in reference to FIGS. 4A-4C, tilting the cradle can accumulate a reaction force in the flexures (e.g., flexures 410-415 of FIG. 4A-4C) based at least in part on deforming the flexures, which applies a force to the front lever arm. To the end of reducing hysteresis and improving precision in motion of the sample cradle, the force compensation mechanism can include a combination of mechanical linkages 560 that are coupled with the linear drive 520 (e.g., via a coupling element 535) and with the holder body 530 via a spring 565 or other element that generates a counteracting force that increases with increasing displacement of the linear drive 520. The spring 565 can be a coil spring, a leaf spring, or other conformation. The mechanical linkages 560 can be coupled at one or more fulcra 570 that configure the mechanical linkages 560 to rotate and maintain a consistent match of the tension in the spring with the reaction force in the flexures at the linear drive 520. In the illustrative embodiment shown in FIG. 5, two mechanical linkages 560 are coupled with the components of the example system 500 at two fulcra 565, with a third fulcrum 570 coupling the two linkages 560 to each other. In this way, a motion of the linear drive 520 in the ±z direction can elicit a motion of the linkages 560 and either deforming the spring 565 or relaxing the spring 565. Advantageously, the action of the force compensation mechanism reacts against the elastic forces accumulated in the flexures of the sample holder to: 1) reduce the monotonic increase in actuator force with increasing displacement of the linear drive 520; and 2) achieve a substantially symmetric load distribution for changing the sample holder between the deformed state and the relaxed states, such that opposing moves can experience reaction forces of a substantially equal magnitude.

FIG. 6A-6B is a schematic diagram illustrating an example measurement system 600, in accordance with some embodiments of the present disclosure. The measurement system 600 includes elements that permit the control circuitry of the sample holder (e.g., control circuitry 235 of FIG. 2, control circuitry 550 of FIG. 5, etc.) to generate precise measurements of a displacement of a linear drive 605. Advantageously, the measurement system 600 can be configured to measure the displacement of the linear drive 605 while applying negligible or no friction to moving components of the sample holder, which could affect the precision of the motion, could generate vibration in the parts. The measurement system 600 can include a pattern 610 disposed and/or formed on a coupler element 615 that couples the linear drive 605 with the tilt mechanism of the sample cradle (e.g., via the rear lever arm). The pattern 610 is oriented toward a measurement sensor 620 and/or device circuitry 625 configured to generate one or more signals based at least in part on a relative position of the pattern 610 and to communicate a position signal with control circuitry (control circuitry 550 of FIG. 5). In this way, the motion of an actuator 635 can be precisely correlated to a linear displacement of the pattern 610. The pattern 610 can be or include optical structure that encodes distances across the pattern 610. For example, the pattern can include one or more high contrast regions (e.g., a barcode) such that the sensor 620 (e.g., an optical encoder) can detect a relatively bright region 640 of the pattern 610 and can determine a relative position of the bright region 640. Where the sensor 620 is a multi-segment photosensor (e.g., a pixelated photo detector) the relative motion of the bright region 640 will generate a position-dependent region of relatively high intensity in the optical data generated by the photosensor that can be correlated to which of the segments are positioned to receive radiation (e.g., infrared photons, visible photons, etc.) from the bright region. In some embodiments, the sensor 620 includes a radiation source configured to emit photons toward the pattern 610. In this way, In this way, the sensor 620 can measure a displacement of the pattern 610, which can result from a displacement of the element 615. Calibration of the sensor signal, in turn, can configure the measurement system 600 to accurately and precisely measure the tilt angle, β, of the sample cradle.

In some embodiments, the sensor 620 includes a strain gauge that is configured to generate a voltage that increases or decreases monotonically in response to a displacement of the element 615. To that end, the strain gauge can include a member that is mechanically coupled with the element 615, such that a linear translation of the element 615 generates a change in the magnitude of the voltage signal generated by the strain gauge (e.g., it can increase or decrease). As with the optical encoder, the strain gauge can be calibrated to provide a precise and accurate measurement of the displacement of the sample cradle.

In the preceding description, various embodiments have been described. For purposes of explanation, specific configurations and details have been set forth in order to provide a thorough understanding of the embodiments. However, it will also be apparent to one skilled in the art that the embodiments may be practiced without the specific details. Furthermore, well-known features may have been omitted or simplified in order not to obscure the embodiment being described. While example embodiments described herein center on charged particle beam systems, and pivot holders in particular, these are meant as non-limiting, illustrative embodiments. Embodiments of the present disclosure are not limited to such embodiments, but rather are intended to address analytical instruments systems for which a wide array of material samples can be analyzed to determine chemical, biological, physical, structural, or other properties, among other aspects, including but not limited to crystalline structure, trace element composition, or the like.

Some embodiments of the present disclosure include a system including one or more data processors and/or logic circuits. In some embodiments, the system includes a non-transitory computer readable storage medium containing instructions which, when executed on the one or more data processors and/or logic circuits, cause the one or more data processors and/or logic circuits to perform part or all of one or more methods and/or part or all of one or more processes and workflows disclosed herein. Some embodiments of the present disclosure include a computer-program product tangibly embodied in non-transitory machine-readable storage media, including instructions configured to cause one or more data processors and/or logic circuits to perform part or all of one or more methods and/or part or all of one or more processes disclosed herein.

The terms and expressions which have been employed are used as terms of description and not of limitation, and there is no intention in the use of such terms and expressions of excluding any equivalents of the features shown and described or portions thereof, but it is recognized that various modifications are possible within the scope of the claims. Thus, it should be understood that although the present disclosure includes specific embodiments and optional features, modification and variation of the concepts herein disclosed may be resorted to by those skilled in the art, and that such modifications and variations are considered to be within the scope of the appended claims.

Where terms are used without explicit definition, it is understood that the ordinary meaning of the word is intended, unless a term carries a special and/or specific meaning in the field of charged particle microscopy systems or other relevant fields. The terms “about” or “substantially” are used to indicate a deviation from the stated property within which the deviation has little to no influence of the corresponding function, property, or attribute of the structure being described. In an illustrated example, where a dimensional parameter is described as “substantially equal” to another dimensional parameter, the term “substantially” is intended to reflect that the two parameters being compared can be unequal within a tolerable limit, such as a fabrication tolerance or a confidence interval inherent to the operation of the system. Similarly, where a geometric parameter, such as an alignment or angular orientation, is described as “about” normal, “substantially” normal, or “substantially” parallel, the terms “about” or “substantially” are intended to reflect that the alignment or angular orientation can be different from the exact stated condition (e.g., not exactly normal) within a tolerable limit. For numerical values, such as diameters, lengths, widths, or the like, the term “about” can be understood to describe a deviation from the stated value of up to ±10%. For example, a dimension of “about 10 mm” can describe a dimension from 9 mm to 11 mm.

The description provides exemplary embodiments, and is not intended to limit the scope, applicability or configuration of the disclosure. Rather, the ensuing description of the exemplary embodiments will provide those skilled in the art with an enabling description for implementing various embodiments. It is understood that various changes may be made in the function and arrangement of elements without departing from the spirit and scope as set forth in the appended claims. Specific details are given in the description to provide a thorough understanding of the embodiments. However, it will be understood that the embodiments may be practiced without these specific details. For example, specific system components, systems, processes, and other elements of the present disclosure may be shown in schematic diagram form or omitted from illustrations in order not to obscure the embodiments in unnecessary detail. In other instances, well-known circuits, processes, components, structures, and/or techniques may be shown without unnecessary detail.

What is claimed is:

1. An apparatus for coupling a specimen with an instrument, the apparatus comprising:
a rear lever arm;
a front lever arm, coupled with the rear lever arm; and
a sample cradle, coupled with the front lever arm via an S-flexure.

2. The apparatus of claim 1, wherein the S-flexure defines a deformed state and a relaxed state, wherein the S-flexure can be reversibly transitioned between the deformed state and the relaxed state, and wherein a transition between the deformed state and the relaxed state induces a pivot of the sample cradle.

3. The apparatus of claim 2, wherein the pivot describes an angle from about-10 degrees to about 10 degrees, relative to a lateral axis of the sample cradle.

4. The apparatus of claim 1, further comprising a holder body, wherein the sample cradle is mechanically coupled with the holder body via a V-flexure.

5. The apparatus of claim 1, wherein the rear lever arm is mechanically coupled with the front lever arm via a pivot coupling, such that a vertical translation of a first end of the rear lever arm induces a complementary translation of the front lever arm in the vertical direction.

6. The apparatus of claim 1, wherein the front lever arm is mechanically coupled with the rear lever arm via a diaphragm.

7. The apparatus of claim 6, further comprising a holder body, wherein the diaphragm is mechanically coupled with the holder body, defining a vacuum-tight seal with the holder body.

8. The apparatus of claim 1, wherein the front lever arm is mechanically coupled with a damper mass via a viscoelastic ligature.

9. The apparatus of claim 8, wherein the damper mass is physically separate from the front lever arm, being disposed in an aperture formed through the front lever arm.

10. The apparatus of claim 9, wherein the aperture is formed at a position on the front lever arm corresponding to a resonant mode or otherwise elevated amplitude of vibratory motion in the front lever arm.

11. The apparatus of claim 1, wherein the rear lever arm is mechanically coupled with a linear drive, the linear drive being configured to translate a first end of the rear lever arm in a vertical direction.

12. The apparatus of claim 11, wherein the rear lever arm is mechanically coupled with a strain gauge.

13. The apparatus of claim 11, further comprising an optical encoder configured to measure a spatial displacement of the linear drive.

14. The apparatus of claim 11, further comprising a force compensation mechanism, mechanically coupled with the linear drive actuator and configured to oppose a force resulting from a translation of the first end by the actuator.

15. A charged particle beam system, comprising:
a source of charged particles, configured to generate a beam of charged particles; and
an objective section configured to direct at least a portion of the beam of charged particles through a sample holder, the sample holder comprising:
a rear lever arm;
a front lever arm, coupled with the rear lever arm; and
a sample cradle, coupled with the front lever arm via an S-flexure.

16. The system of claim 15, wherein the S-flexure defines a deformed state and a relaxed state, wherein the S-flexure can be reversibly transitioned between the deformed state and the relaxed state, and wherein a transition between the deformed state and the relaxed state induces a pivot of the sample cradle.

17. The system of claim 15, wherein the sample holder further comprises further a holder body, and wherein the sample cradle is mechanically coupled with the holder body via a V-flexure.

18. The system of claim 15, wherein the front lever arm is mechanically coupled with the rear lever arm via a diaphragm.

19. The system of claim 18, further comprising a holder body, wherein the diaphragm is mechanically coupled with the holder body, defining a vacuum-tight seal with the holder body.

20. The system of claim 15, wherein the front lever arm is mechanically coupled with a damper mass via a viscoelastic ligature, and wherein the damper mass is physically separate from the front lever arm, being disposed in an aperture formed through the front lever arm.
